(19) United States
(12) Patent Application Publication
(10) Pub. No.: US 2010/0096678 A1
(43) Pub. Date: Apr. 22, 2010

(54) NANOSTRUCTURED BARIUM STRONTIUM TITANATE (BST) THIN-FILM VARACTORS ON SAPPHIRE

(75) Inventor: Guru Subramanyam, Dayton, OH (US)

Correspondence Address: DINSMORE & SHOHL LLP, FIFTH THIRD CENTER, ONE SOUTH MAIN STREET, SUITE 1300, DAYTON, OH, 45402-2023, US

(73) Assignee: University of Dayton, Dayton, OH (US)

(21) Appl. No.: 12/254,256

(22) Filed: Oct. 20, 2008

(51) Int. Cl. H01L 29/93

(52) U.S. Cl. 257/295; 977/755; 257/E29.344; 257/E27.049

(57) ABSTRACT

Varactor shunt switches based on a nonlinear dielectric tunability of BaₓSr₍₁₋ₓ₎TiO₃ (BST) thin-film on a sapphire substrates are presented. Nanostructured BST thin-films with dielectric tunability as high as 4.3:1 can be obtained on sapphire substrates, with very low loss-tangents below 0.025 at zero-bias and 20 GHz. The large capacitance of the varactor at zero bias can shunt the input signal to ground isolating the output port, resulting in the OFF state. When applying a bias voltage of approximately 10 V (a dc electric field of ˜250 kV/cm), the varactor's capacitance can be reduced to a minimum, allowing maximum transmission to the output resulting in the ON state. The microwave switching performance of the varactor shunt switch can be compared with the RF MEMS switches for potential applications at microwave and millimeterwave frequencies. Other applications of such BST varactors include tunable filters, phase shifter circuits and impedance matching circuits

### BACKGROUND

The present disclosure generally relates to barium strontium titanate (BST) thin-film varactors and, in particular, relates to nanostructured barium strontium titanate (BST) thin-film varactors on a sapphire substrate.

High K tunable, microwave dielectrics such as barium strontium titanate (BaₓSr₍₁₋ₓ₎TiO₃), or BST, are gaining acceptance in microwave integrated circuits due to a large need for tunable/reconfigurable circuits. Recent developments on tunable dielectrics have shown that the varactors made of BST ferroelectric thin-films can have constant Q through millimeterwave frequencies. Semiconductor varactor diodes and PIN diodes can have relatively large Q below 10 GHz, but the Q can drop down drastically above 10 GHz making them less attractive for applications above 10 GHz. Radio frequency (RF) microelectromechanical system (MEMS) switches can offer high Q at microwave and millimeterwave frequencies, but can be complex in nature, and the slow speed of switching can be undesirable for many applications. Ferroelectric varactors can be characterized by fast switching speed, ease of integration with silicon (Si) monolithic microwave integrated circuits (MMICs), and can have reasonable Q at microwave and millimeterwave frequencies.

Recently, the use of sapphire (aluminum oxide or Al₂O₃) as a substrate has gained popularity for lattice matching and epitaxial growth applications. The advantage of sapphire substrates is that sapphire tends to be an excellent electrical insulator at microwave frequencies. In addition, sapphire can also have application as a low loss microwave substrate. However, most of these applications using a sapphire substrate also use a large-grained thin film (i.e., thin film with a grain size greater than 150 nm) for the dielectric layer and tend to be on the microstructure level.

However, there is a need for a large dielectric tunability and low loss-tangent in BST thin films for varactor applications. Nanostructured small-grained BST thin films provide large dielectric tunability and low loss-tangents at microwave and millimeterwave frequencies. Nanostructured BST thin film-based varactor shunt switches fabricated on sapphire substrates exhibit improved RF performance characteristics.

### BRIEF SUMMARY

According to the present disclosure, a varactor shunt switch for microwave applications is presented. The varactor shunt switch can comprise a sapphire substrate, a bottom metal layer deposited on the sapphire substrate, a tunable thin-film dielectric layer on the bottom metal layer, and a top metal layer on the tunable thin-film dielectric layer. The top metal layer can define a coplanar waveguide transmission line.

In accordance with one embodiment, the varactor shunt switch can be constructed using nanostructured BST thin film as a tunable dielectric.

In accordance with another embodiment, the tunable thin-film dielectric layer can be small-grained barium strontium titanate.

Accordingly, it is a feature of the embodiments of the present disclosure to improve the tunability and RF performance of a nanostructured BST thin film varactor by reducing the substrate dielectric losses through the use of a sapphire substrate. Other features of the embodiments of the present disclosure will be apparent in light of the description of the disclosure embodied herein.

### BRIEF DESCRIPTION OF THE SEVERAL VIEWS OF THE DRAWINGS

The following detailed description of specific embodiments of the present disclosure can be best understood when read in conjunction with the following drawings, where like structure is indicated with like reference numerals and in which:

FIG. 1 illustrates a top-view of a varactor shunt switch according to an embodiment of the present disclosure.

FIG. 2 illustrates a three dimensional view of the device according to an embodiment of the present disclosure.

FIG. 3 illustrates a simple electrical model for the varactor shunt switch in the ON state for a 5×5 μm² device according to an embodiment of the present disclosure.

FIG. 4 graphs the measured bias dependence of S₂₁ for a 5×5 μm² varactor shunt switch according to an embodiment of the present disclosure.

FIG. 5 graphs the measured bias dependence of S₁₁ for a 5×5 μm² varactor shunt switch according to an embodiment of the present disclosure.

FIG. 6 graphs the capacitance vs. voltage characteristics for the nanostructured BST varactor on sapphire according to an embodiment of the present disclosure.

FIG. 7 graphs the dielectric properties of a nanostructured BST thin film on sapphire substrate according to an embodiment of the present disclosure.

### DETAILED DESCRIPTION

In the following detailed description of the embodiments, reference is made to the accompanying drawings that form a part hereof, and in which are shown by way of illustration, and not by way of limitation, specific embodiments in which the disclosure may be practiced. It is to be understood that other embodiments may be utilized and that logical, mechanical and electrical changes may be made without departing from the spirit and scope of the present disclosure.

Briefly, the varactor shunt switch 10 can comprise of a CPW transmission line loaded by a varactor in the middle, such that the large capacitance of the varactor at zero bias will shunt the input signal to ground, thus isolating the output port, resulting in the OFF state of the device. When applying a bias voltage corresponding to a dc field of ˜250 kV/cm, (approximately 10 V), the varactor's capacitance can be reduced to a minimum, allowing most of the signal from the input to be transmitted to the output, thus resulting in the ON state of the device.

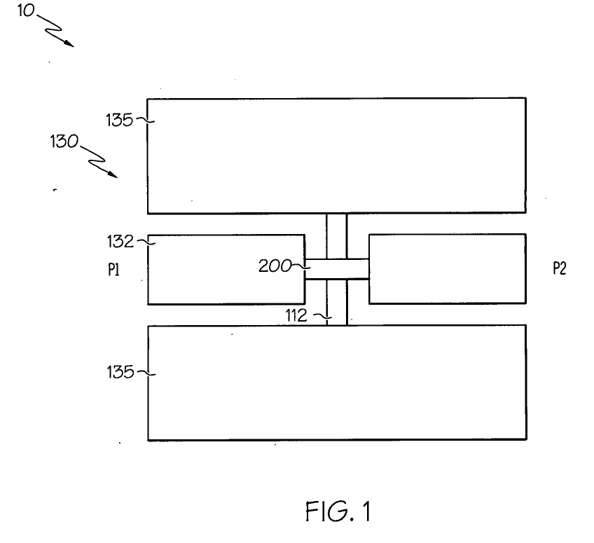

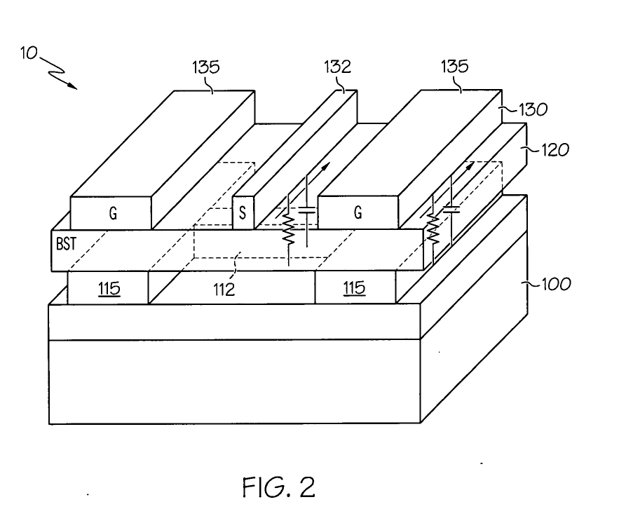

Referring initially to FIGS. 1 and 2, a nanostructured varactor shunt switch 10 can be designed using a coplanar waveguide (CPW) transmission line on a sapphire substrate 100. The thickness of the sapphire substrate 100 can range between about 100 μm to about 1000 μm and can typically be around 500 μm. The sapphire substrate 100 can typically have a R-plane orientation. However, the sapphire substrate 100 can also have other orientations as needed, such as, for example, A-plane which can also be referred to as 90-degree sapphire, C-plane which can be referred to as 0-degree or basal plane sapphire or any other suitable orientation.

The varactor shunt switch 10 can have a top metal layer 130 and a bottom metal layer 110 with a tunable thin film layer 120 between the bottom metal layer 110 and top metal layer 130. In one exemplary embodiment, the tunable dielectric thin film layer 120 can be nanostructured BST. The nanostructured BST thin film 120 can refer to a BST thin film having a grain size less than 100 nm. In one exemplary embodiment, the nanostructured BST thin film 120 can have an average grain size of approximately 30 nm to approximately 100 nm. In one embodiment, the top metal layer 130 can comprise a probe-able CPW line for on-wafer probe measurements. Both bottom metal layer 110 and top metal layer 130 can comprise the large ground lines 115, 135, resulting in large capacitors due to the nanostructured BST thin film layer 120 positioned between the top metal layer 130 and the bottom metal layer 110.

In FIG. 1, a top-view of a varactor shunt switch 10 showing the top metal layer 130 and part of the bottom metal layer 110 is shown. The overlap area of the top metal layer's signal conductor 132 and bottom metal layer's shunt line 112 can define the varactor area 200. P1 can represent the input port and P2 can represent the output port. The bottom metal layer 110 can comprise of a shunt line 112 connecting the two ground lines 115 (not shown in FIG. 1) in the bottom metal layer 110.

FIG. 1 shows a parallel plate varactor 10 being created in the overlapping area of the center conductor 132 in the top metal layer 130 and the thin shunt line 112 in the bottom metal layer 110. The varactor capacitance can essentially be in series with the large capacitance defined by the overlap area of the ground lines 115, 135 in the bottom metal layer 110 and the top metal layer 130, resulting in an effective capacitance of the varactor. In one embodiment, the shunt conductances of the varactor and the large overlapping capacitance of the ground lines, can help eliminate any need for via holes, resulting in a simpler process. In FIG. 2, G, S and G stand for Ground-Signal-Ground of the CPW in top metal layer 130. In one exemplary embodiment, the varactor shunt switch 10 area can be approximately 450 μm×500 μm. In one embodiment, CPW Ground-Signal-Ground dimensions can be approximately 150 μm/50 μm/150 μm on the sapphire substrate 100 for obtaining a characteristic impedance close to 50 ohms at zero-bias. The spacing between the center conductor 132 and ground conductors 135 can be about 50 μm.

A three dimensional view of the varactor shunt switch 10 showing the varactor 200 in the middle, and the large series capacitance due to the overlapping ground lines 115, 135 is shown in FIG. 2. The shunt line 112 of the bottom metal layer 110 can also present a parasitic series inductance and resistance to the varactor 200.

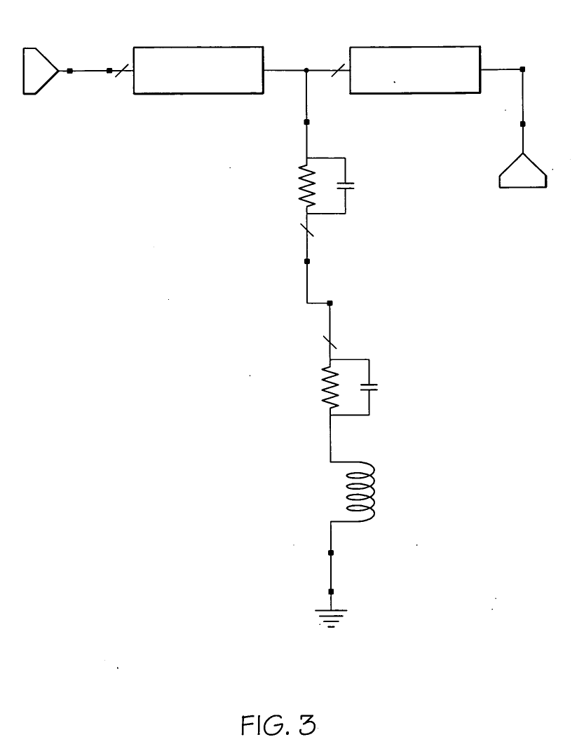

The important device parameters to be considered can be (i) the varactor area 200, (ii) CPW transmission line parameters, such as the width of the center conductor 132, spacing between the center conductor 132 and ground lines 135, and length of the CPW line sections, (iii) parasitic inductance and resistance of the thin-line shunting to ground in the bottom metal layer 110, and (iv) the dielectric properties of the nanostructured BST thin-film 120. The varactor shunt switch 10 can be precisely modeled. FIG. 3 shows the simple electrical model for the varactor shunt switch 10. The parasitic inductance and resistance can be precisely calculated through the use of the electrical model.

The larger area of the varactor can result in a large zero-bias capacitance of the varactor. Varactor shunt switches 10 can be designed for a specific frequency range of operation, as the off-state resonance frequency determines the maximum isolation of the switch. Large area varactors can result in high isolation, at the same time, increasing the insertion loss of the switch. Ideally, the varactor capacitance can be reduced to the level of the line capacitance to obtain low insertion loss in the ON state. This requirement can be difficult to achieve in the case of large area varactors, as the dielectric tunability is limited to approximately 4:1 in BST thin films 120 on high resistivity Si substrate. However, a larger dielectric tunability of greater than 4:1 can be possible using low loss microwave substrates such as sapphire 100.

In one exemplary embodiment, the bottom metal layer 110 can comprise a metal stack. Standard positive photoresist lift-off photolithography can be used for the bottom metal layer, or stack, 110 with a Ti adhesion layer (20 nm) deposited first followed by 800 nm of gold and 200 nm of platinum to make up the bottom metal layer 110 in an electron-beam evaporation system. Lift-off photolithography can also be used for to deposit the bottom metal layer 110 or any other suitable deposition method. After the bottom metal layer 110 was defined, the nanostructured Ba_{0.6}Sr_{0.4}TiO₃ (BST) thin-film 120 can be deposited on the entire surface of the bottom metal layer 110 in a process controlled pulsed laser deposition system. The small-grained BST thin film 120 can also be deposited by sputtering, chemical vapor deposition, sol-gel method, or by any other suitable deposition method.

The nanostructured BST thin film 120 can be processed at oxygen partial pressure below about 150 mTorr in a large area deposition system (Neocera pioneer 180 capable of deposition on 4″ diameter wafers) which can result in an average grain-size of the BST thin film 120 of approximately 30 nm to approximately 100 nm. The nanostructured BST thin-films 120 can be fabricated by any suitable method known in the art such as, for example, RF sputtering and metal organic chemical vapor deposition (MOCVD). After the BST thin film 120 deposition, the top metal layer 130 can be defined and processed using a lift-off technique to complete the varactor shunt switch 10 fabrication. The top metal layer 130 can be defined by e-beam deposition (or sputtering) or by any other suitable method. The top metal layer 130 can also be comprised of a metal stack.

The resulting varactor shunt switches can be tested and scattering (S) parameters can be measured using a HP 8510 Vector Network Analyzer (VNA). First, a Line-Reflect-Reflect-Match (LRRM) calibration can be done over a wide frequency range (approximately 5 to approximately 45 GHz). The sample can be probed using standard GSG probes, with the dc bias applied through the bias tee of the VNA to the probe.

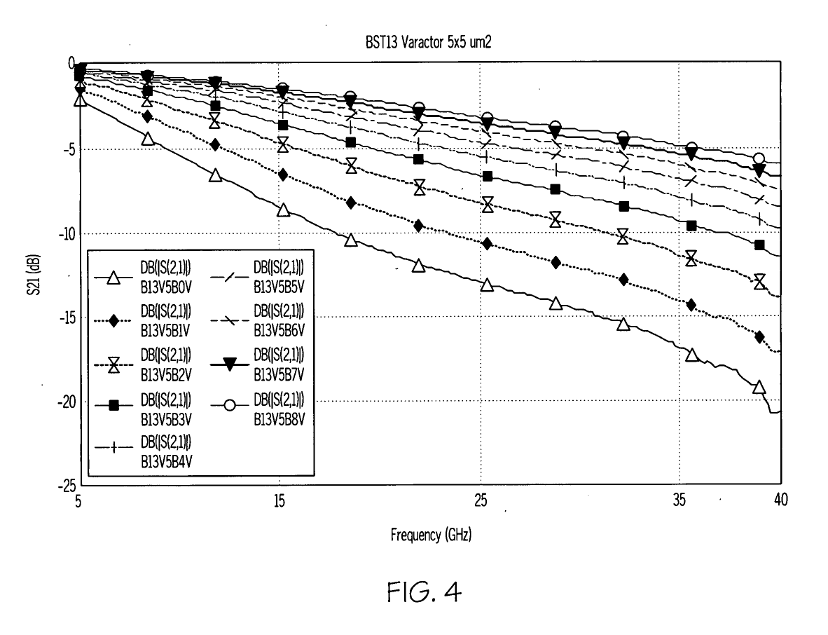

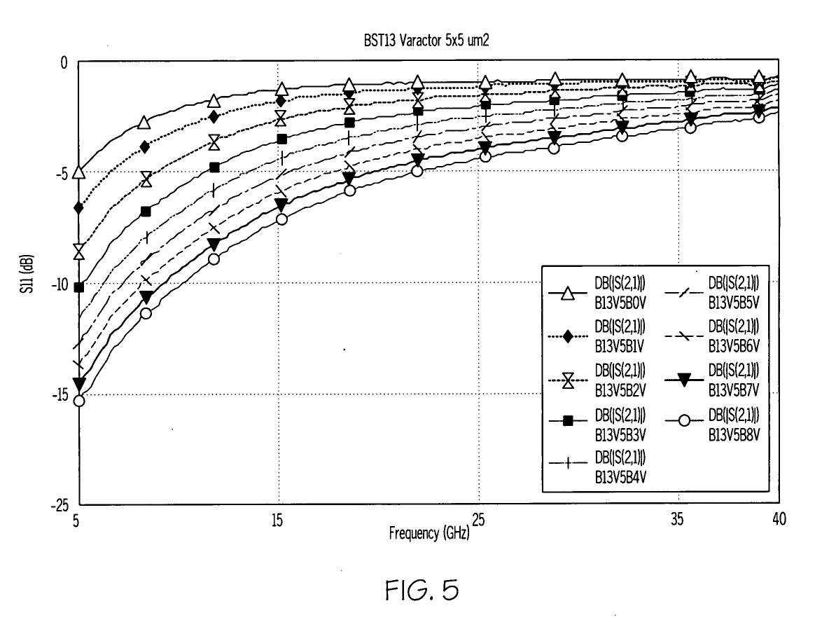

Experimental results have been obtained on several 5×5 μm² varactor shunt switches. One of the devices was tested up to 45 GHz. The swept frequency S₂₁ (i.e., the ratio of transmitted power to input power) response for bias voltages from zero to 9V for a step size of 1 V is shown in FIG. 4. As can be seen in the graph, the isolation of the switch at 40 GHz can be approximately 21 dB. The insertion loss of the device at the highest bias voltage (8 V) and 40GHz can be ˜6 dB. The bias dependence of S₁₁ (i.e., the input voltage reflection coefficient) for the same device is shown in FIG. 5. The bias dependence of S₁₁ is shows nonlinear bias dependence similar to S₂₁.

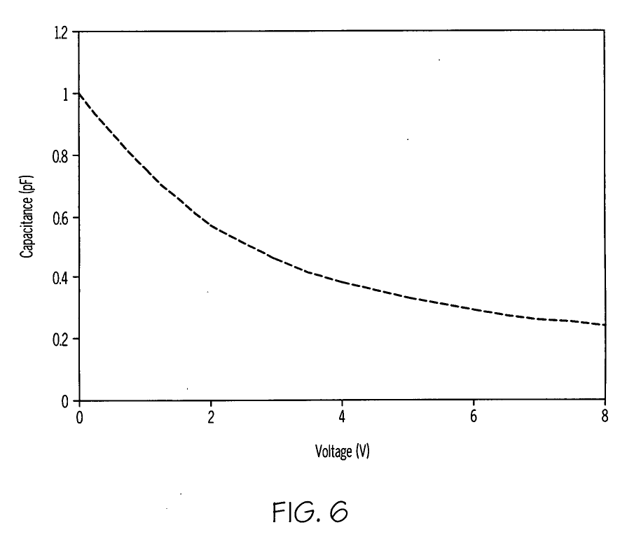

FIG. 6 illustrates Capacitance versus Voltage characteristics for the nanostructured BST thin film varactor on sapphire. As can be seen by the graph, capacitance decreases with increasing voltage. The capacitance at zero-bias can be approximately 1 pF for a 5 μm×5 μm varactor device, which can be almost 1.5 times higher than what can be obtained in the same varactor device on high resistivity Si substrate. The capacitance can be nonlinearly tunable to about 0.23 pF at 8 V dc bias.

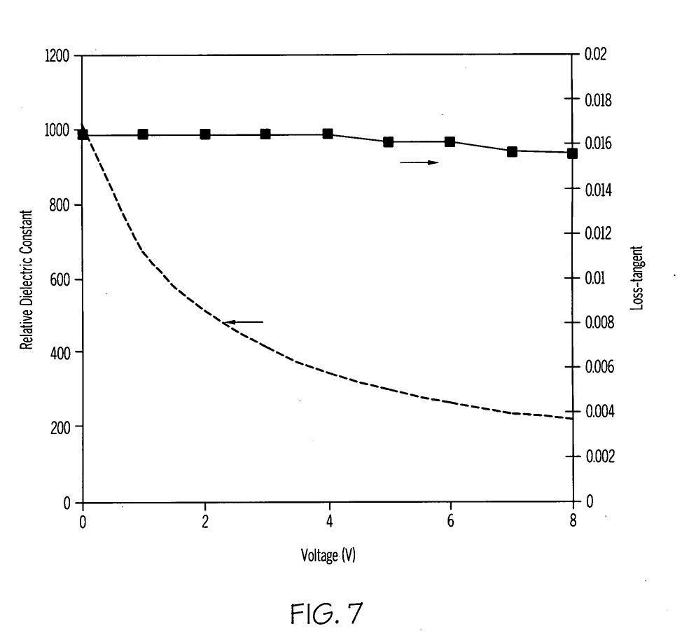

FIG. 7 illustrates the dielectric properties of nanostructured BST thin film on sapphire substrate, extracted by matching the experimental swept frequency S-parameters to the swept frequency S-parameters obtained using an equivalent circuit model. It is very clear that the dielectric tunability can be much higher than what has been measured on high resistivity Si wafers. Also, the dielectric loss-tangent can be below 0.02 over the entire bias voltage range. Note that the dielectric loss-tangent was calculated at 20 GHz. Recently, dielectric loss-tangent below 0.006 has been obtained on nanostructured BST thin films on Sapphire substrates, which can result in improved Q of BST varactors.

The varactor shunt switch can be a normally OFF device which operates based on the dielectric tunability of the small-grained BST thin-film with applied dc bias. The capacitance of the varactor can be tunable by more than 3.5:1 to achieve a good switching behavior. In one exemplary embodiment, nanostructured BST thin-films with dielectric tunability as high as 4.3:1 can be obtained on sapphire substrates, with very low loss-tangents below 0.025 at zero-bias and 20 GHz.

Such a varactor shunt switch 10 device can be a good competitor for RF MEMS capacitive shunt switches in reconfigurable/tunable microwave circuits. The varactor shunt switch 10 can be a very simple device which is easier to integrate with sapphire substrates 100 for MMICs. The simulation results predict that the switch can be a low loss switch for millimeterwave frequencies. Large number of applications including tunable filters, phase shifters, and potential wireless sensors can be developed.

It is noted that terms like “preferably,” “commonly,” and “typically” are not utilized herein to limit the scope of the claimed disclosure or to imply that certain features are critical, essential, or even important to the structure or function of the claimed disclosure. Rather, these terms are merely intended to highlight alternative or additional features that may or may not be utilized in a particular embodiment of the present disclosure.

For the purposes of describing and defining the present disclosure it is noted that the term “substantially” is utilized herein to represent the inherent degree of uncertainty that may be attributed to any quantitative comparison, value, measurement, or other representation. The term “substantially” is also utilized herein to represent the degree by which a quantitative representation may vary from a stated reference without resulting in a change in the basic function of the subject matter at issue.

Having described the disclosure in detail and by reference to specific embodiments thereof, it will be apparent that modifications and variations are possible without departing from the scope of the disclosure defined in the appended claims. More specifically, although some aspects of the present disclosure are identified herein as preferred or particularly advantageous, it is contemplated that the present disclosure is not necessarily limited to these preferred aspects of the disclosure.

What is claimed is:

1. A varactor shunt switch for microwave applications, the varactor shunt switch comprising:
a sapphire substrate;
a bottom metal layer stack deposited on the sapphire substrate;
a tunable nanostructured thin-film dielectric layer on the bottom metal layer; and
a top metal layer stack on said tunable thin-film dielectric layer, wherein said top metal layer defines a coplanar waveguide transmission line.

2. The varactor shunt switch of claim 1, wherein the sapphire substrate has a R-plane, C-plane or A-plane orientation.

3. The varactor shunt switch of claim 1, wherein the sapphire substrate has a R-plane orientation.

4. The varactor shunt switch of claim 1, wherein the sapphire substrate has a thickness of about 100 μm to about 500 μm.

5. The varactor shunt switch of claim 1, wherein the bottom metal layer stack is comprised of gold and platinum and a titanium adhesion layer.

6. The varactor shunt switch of claim 1, wherein the tunable thin-film dielectric layer is barium strontium titanate.

7. The varactor shunt switch of claim 1, wherein the tunable thin-film dielectric layer is nanostructured.

8. The varactor shunt switch of claim 1, wherein the tunable thin-film dielectric layer has an average grain size of less than 100 nm.

9. The varactor shunt switch of claim 1, wherein the tunable thin-film dielectric layer has a grain size that ranges from about 30 nm to about 100 nm.

10. The varactor shunt switch of claim 1, wherein the tunable thin-film dielectric layer is processed at about 30 mT to about 150 mT oxygen partial pressure.

11. The varactor shunt switch of claim 1, further comprising,
an adhesion layer on the sapphire substrate, wherein the adhesion layer is deposited before the deposition of the bottom metal layer stack.

12. The varactor shunt switch of claim 1, wherein the varactor shunt switch has a dielectric tunability of greater than 4.

13. The varactor shunt switch of claim 1, wherein the varactor shunt switch has a dielectric tunability of 4.3.

14. The varactor shunt switch of claim 1, wherein the varactor shunt switch has a loss-tangent below 0.025 at zero bias and 20 GHz.

15. A varactor shunt switch for microwave applications, the varactor shunt switch comprising:
a sapphire substrate;
a bottom metal layer on the sapphire substrate;
a tunable barium strontium titanate thin-film dielectric layer on the bottom metal layer; and
a top metal layer on the tunable thin-film dielectric layer, wherein said top metal layer defines a coplanar waveguide transmission line.

16. A varactor shunt switch for microwave applications, the varactor shunt switch comprising:
a sapphire substrate;
a bottom metal layer on the sapphire substrate;
a tunable nanostructured barium strontium titanate thin-film dielectric layer on the bottom metal layer; and
a top metal layer on the tunable nanostructured thin-film dielectric layer, wherein said top metal layer defines a coplanar waveguide transmission line.
